(19) United States
(12) Patent Application Publication
(10) Pub. No.: US 2025/0089573 A1
(43) Pub. Date: Mar. 13, 2025

(54) POLYMER, COMPOSITION, PIEZOELECTRIC COMPOSITE MATERIAL, PIEZOELECTRIC FILM AND PIEZOELECTRIC ELEMENT

(71) Applicant: FUJIFILM Corporation, Tokyo (JP)

(72) Inventors: Wataru KIKUCHI, Minamiashigara-shi (JP); Naoyuki MOROOKA, Minamiashigara-shi (JP); Mikio ONO, Minamiashigara-shi (JP)

(73) Assignee: FUJIFILM Corporation, Tokyo (JP)

(21) Appl. No.: 18/954,767

(22) Filed: Nov. 21, 2024

Related U.S. Application Data
(63) Continuation of application No. PCT/JP2023/022339, filed on Jun. 16, 2023.

(30) Foreign Application Priority Data
Jun. 30, 2022 (JP) 2022-105419

(51) Int. Cl. H10N 30/85; C08F 16/28; H04R 17/00; H10N 30/092

(52) U.S. Cl. CPC H10N 30/852; C08F 16/28; H04R 17/005; H10N 30/092

(57) ABSTRACT

The present invention provides a polymer which has a small change in relative permittivity before and after exposure to a high-temperature and high-humidity environment, and is capable of forming a film having few wrinkles; a composition; a piezoelectric composite material; a piezoelectric film; and a piezoelectric element. The polymer of an embodiment of the present invention is a polymer including a repeating unit represented by Formula (A) and a repeating unit represented by Formula (B), in which a content of the repeating unit represented by Formula (A) is 60% by mole or more with respect to all repeating units of the polymer, a content of the repeating unit represented by Formula (B) is 1% to 40% by mole with respect to all repeating units of the polymer, and the polymer includes no repeating unit represented by Formula (C), or in a case where the polymer includes the repeating unit represented by Formula (C), a content of the repeating unit represented by Formula (C) is 5% by mole or less with respect to all repeating units of the polymer.

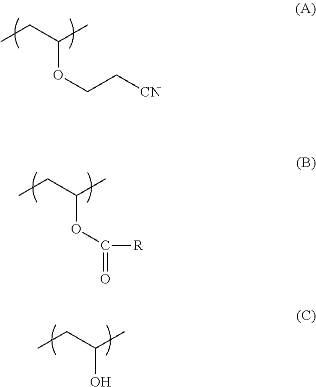

### CROSS-REFERENCE TO RELATED APPLICATIONS

This application is a Continuation of PCT International Application No. PCT/JP2023/022339 filed on Jun. 16, 2023, which claims priority under 35 U.S.C. § 119(a) to Japanese Patent Application No. 2022-105419 filed on Jun. 30, 2022. The above applications are hereby expressly incorporated by reference, in their entirety, into the present application.

### BACKGROUND OF THE INVENTION

### 1. Field of the Invention

The present invention relates to a polymer, a composition, a piezoelectric composite material, a piezoelectric film, and a piezoelectric element.

### 2. Description of the Related Art

In the related art, a cyanoethyl compound and the like are known as an organic material having a high relative permittivity, and have been applied to various uses such as an organic electroluminescent light emitting element and a capacitor.

As such a material having a high relative permittivity, for example, JP1994-196022A (JP-H06-196022A) discloses “a highly dielectric material obtained by substituting a compound selected from an oligosaccharide, a polysaccharide, a polyvinyl alcohol, and derivatives thereof with a cyanoethyl group and a saturated fatty acid ester group having 10 to 20 carbon atoms, in which a substitution rate of the cyanoethyl group is 60% or more and a substitution rate of the saturated fatty acid ester group having 10 to 20 carbon atoms is 5% to 40%”.

### SUMMARY OF THE INVENTION

On the other hand, in recent years, there has been an increasing demand for further improvement in performance of such a material having a high relative permittivity.

For example, it is desired that a change in relative permittivity exhibited by a material is small before and after the material is exposed to a high-temperature and high-humidity environment. In addition, in a film including the material, it is desired that the occurrence of shape defects such as a wrinkle is suppressed.

The present inventors have conducted an investigation on the characteristics of the highly dielectric material described in JP1994-196022A (JP-H06-196022A), and have thus found that the required characteristics are not sufficiently satisfied and there is a need of further improvement.

An object of the present invention is to provide a polymer which has a small change in relative permittivity before and after exposure to a high-temperature and high-humidity environment, and is capable of forming a film having few wrinkles.

Another object of the present invention is to provide a composition, a piezoelectric composite material, a piezoelectric film, and a piezoelectric element.

In order to accomplish the objects, the present invention has the following configurations.

(1) A polymer comprising:
a repeating unit represented by Formula (A) and a repeating unit represented by Formula (B),
in which a content of the repeating unit represented by Formula (A) is 60% by mole or more with respect to all repeating units of the polymer,
a content of the repeating unit represented by Formula (B) is 1% to 40% by mole with respect to all repeating units of the polymer, and
the polymer includes no repeating unit represented by Formula (C), or
in a case where the polymer includes the repeating unit represented by Formula (C), a content of the repeating unit represented by Formula (C) is 5% by mole or less with respect to all repeating units of the polymer.

(2) The polymer according to (1),
in which the aliphatic hydrocarbon group which may have a substituent has 2 to 8 carbon atoms.

(3) The polymer according to (1) or (2),
in which the content of the repeating unit represented by Formula (A) is 70% by mole or more with respect to all repeating units of the polymer, and
the content of the repeating unit represented by Formula (B) is 1% to 30% by mole with respect to all repeating units of the polymer.

(4) A composition comprising:
the polymer according to any one of (1) to (3); and
a cyano group-containing compound different from the polymer.

(5) The composition according to (4),
in which the cyano group-containing compound is a compound represented by Formula (1) which will be described later.

(6) The composition according to (4) or (5),
in which the cyano group-containing compound is cyanoethyl sucrose.

(7) A piezoelectric composite material comprising:
the polymer according to any one of (1) to (3); and
piezoelectric particles.

(8) The piezoelectric composite material according to (7),
in which the piezoelectric particles include ceramic particles having a perovskite-type or wurtzite-type crystal structure.

(9) The piezoelectric composite material according to (7) or (8),
in which the piezoelectric particles include any of lead zirconate titanate, lead lanthanum zirconate titanate, barium titanate, zinc oxide, or a solid solution of barium titanate and bismuth ferrite.

(10) The piezoelectric composite material according to any one of (7) to (9), further comprising:
a cyano group-containing compound different from the polymer.

(11) A piezoelectric film comprising:
a piezoelectric layer including the piezoelectric composite material according to any one of (7) to (10); and electrode layers provided on both surfaces of the piezoelectric layer.

(12) A piezoelectric element comprising:
the piezoelectric film according to (11).

According to the embodiment of the present invention, it is possible to provide a polymer which has a small change in relative permittivity before and after exposure to a high-temperature and high-humidity environment, and is capable of forming a film having few wrinkles.

In addition, according to the embodiment of the present invention, it is possible to provide a composition, a piezoelectric composite material, a piezoelectric film, and a piezoelectric element.

### BRIEF DESCRIPTION OF THE DRAWINGS

FIG. 1 is a view schematically showing an example of a piezoelectric film according to an embodiment of the present invention.

FIG. 2 is a conceptual view for describing an example of a method for manufacturing the piezoelectric film.

FIG. 3 is a conceptual view for describing an example of the method for manufacturing the piezoelectric film.

FIG. 4 is a conceptual view for describing an example of the method for manufacturing the piezoelectric film.

FIG. 5 is a view conceptually showing an example of a piezoelectric speaker using the piezoelectric film.

### DESCRIPTION OF THE PREFERRED EMBODIMENTS

Hereinafter, a polymer, a composition, a piezoelectric composite material, a piezoelectric film, and a piezoelectric element according to embodiments of the present invention will be described in detail based on preferred embodiments shown in the accompanying drawings.

Descriptions on the configuration requirements which will be described later are made based on representative embodiments of the present invention in some cases, but it should not be construed that the present invention is limited to such embodiments.

Furthermore, in the present specification, a numerical range expressed using “to” means a range that includes the preceding and succeeding numerical values of “to” as the lower limit value and the upper limit value, respectively.

In addition, the bonding direction of a divalent group described in the present specification is not limited unless otherwise specified. For example, in a case where Y in a compound represented by General Formula “X—Y—Z” is —COO—, Y may be —CO—O— or may be —O—CO—. That is, the compound may be “X—CO—O—Z” or “X—O—CO—Z”.

A feature point of the polymer of the embodiment of the present invention may be that the polymer includes a predetermined amount of a predetermined repeating unit. The repeating unit represented by Formula (A) is a repeating unit related to dielectric characteristics, and an excellent relative permittivity is accomplished by including a predetermined amount or more of the repeating unit represented by Formula (A). In addition, the repeating unit represented by Formula (B) is a repeating unit capable of imparting hydrophobicity to the polymer, whereas the repeating unit represented by Formula (C) corresponds to a repeating unit capable of imparting hydrophilicity to the polymer. In the present invention, by adjusting the content of the repeating unit represented by Formula (B) and the repeating unit represented by Formula (C), a change in relative permittivity can be decreased before and after the polymer is exposed to a high-temperature and high-humidity environment, and the occurrence of wrinkles in the film including the polymer can be suppressed. In particular, it has been found that the occurrence of wrinkles in a film including the polymer is suppressed by adjusting the number of carbon atoms in a group represented by R in the repeating unit represented by Formula (B) to a predetermined range. The details of the reason why the occurrence of such wrinkles is suppressed are not clear, but it is presumed that the thermal and mechanical characteristics of the polymer are adjusted and the occurrence of wrinkles is suppressed by adjusting the number of carbon atoms in the group represented by R.

### <Polymer>

The polymer of an embodiment of the present invention (hereinafter also simply referred to as the “polymer”) is a polymer including a repeating unit represented by Formula (A) and a repeating unit represented by Formula (B), in which a content of the repeating unit represented by Formula (A) is 60% by mole or more with respect to all repeating units of the polymer, a content of the repeating unit represented by Formula (B) is 1% to 40% by mole or more with respect to all repeating units of the polymer, and the polymer includes no repeating unit represented by Formula (C), or in a case where the polymer includes the repeating unit represented by Formula (C), a content of the repeating unit represented by Formula (C) is 5% by mole or less with respect to all repeating units of the polymer.

Hereinafter, the characteristics of the polymer will be described in detail.

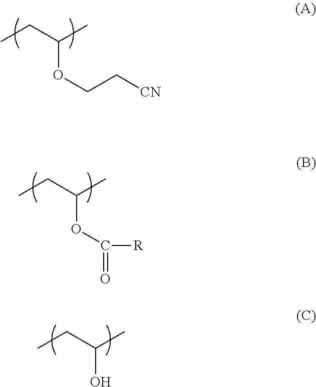

### (Repeating Unit Represented by Formula (A))

The repeating unit represented by Formula (A) is a repeating unit having a cyanoethyl group.

The content of the repeating unit represented by Formula (A) is 60% by mole or more, and from the viewpoint of obtaining at least one of an effect of obtaining a smaller change in relative permittivity before and after exposure to a high-temperature and high-humidity environment, and an effect of making it possible to form a film having fewer wrinkles (hereinafter also simply referred to as “the effect of the present invention is more excellent”), the content is preferably 70% by mole or more, and more preferably 80% by mole or more.

An upper limit value of the content of the repeating unit represented by Formula (A) is not particularly limited, but is preferably 99% by mole or less, and more preferably 98% by mole or less with respect to all repeating units of the polymer.

### (Repeating Unit Represented by Formula (B))

In Formula (B), R represents an aliphatic hydrocarbon group which may have a substituent.

The aliphatic hydrocarbon group may be linear, branched, or cyclic. Among these, the aliphatic hydrocarbon group is preferably linear from the viewpoint that the effect of the present invention is more excellent.

The aliphatic hydrocarbon group may be a saturated aliphatic hydrocarbon group or may be an unsaturated aliphatic hydrocarbon group. Among these, the aliphatic hydrocarbon group is preferably an alkyl group. That is, R is preferably an alkyl group which may have a substituent.

The type of the substituent which the aliphatic hydrocarbon group may have is not particularly limited, and examples thereof include an aryl group, an amino group, an alkoxy group, an aryloxy group, an aromatic heterocyclic oxy group, an acyl group, an alkoxycarbonyl group, an aryloxycarbonyl group, an acyloxy group, an acylamino group, an alkoxycarbonylamino group, an aryloxycarbonylamino group, an alkylthio group, an arylthio group, an aromatic heterocyclic thio group, a ureido group, a halogen atom, a cyano group, a hydrazino group, a heterocyclic group (for example, a heteroaryl group), a silyl group, and a group obtained by combining these groups.

Among these, polymerizable groups such as an acryloyl group and a methacryloyl group are preferable as the substituent.

The number of carbon atoms in the aliphatic hydrocarbon group which may have a substituent, represented by R, is 1 to 8, and from the viewpoint that the effect of the present invention is more excellent, the number of carbon atoms is preferably 2 to 8, and more preferably 2 to 5.

Furthermore, the number of carbon atoms means the number of carbon atoms included in the entire aliphatic hydrocarbon group which may have a substituent. Therefore, in a case where the aliphatic hydrocarbon group which may have a substituent does not have a substituent (that is, in a case where R is an unsubstituted aliphatic hydrocarbon group), it means that the number of carbon atoms included in the aliphatic hydrocarbon group itself is 1 to 8. In addition, in a case where the aliphatic hydrocarbon group which may have a substituent has a substituent (that is, in a case where R is an aliphatic hydrocarbon group having a substituent), the total of the number of carbon atoms included in the aliphatic hydrocarbon group and the number of carbon atoms included in the substituent is 1 to 8. For example, in a case where R is an ethyl group having an acryloyl group (CH₂═CH—CO—), the total number of carbon atoms is calculated as 5, which is a total of 3 in the acryloyl group and 2 in the ethyl group.

The content of the repeating unit represented by Formula (B) is 1% to 40% by mole with respect to all repeating units of the polymer, and from the viewpoint that the effect of the present invention is more excellent, the content is preferably 1% to 30% by mole, and more preferably 5% to 30% by mole.

### (Repeating Unit Represented by Formula (C))

The polymer may or may not include a repeating unit represented by Formula (C). Among these, from the viewpoint that the effect of the present invention is more excellent, it is preferable that the polymer does not include the repeating unit represented by Formula (C).

In a case where the polymer includes the repeating unit represented by Formula (C), the content of the repeating unit represented by Formula (C) is 5% by mole or less, preferably 0.5% to 5% by mole, and more preferably 1% to 3% by mole with respect to all repeating units of the polymer.

The total content of the repeating unit represented by Formula (A), the repeating unit represented by Formula (B), and the repeating unit represented by Formula (C) is preferably 90% by mole or more, and more preferably 95% by mole or more with respect to all repeating units of the polymer.

The upper limit of the total content is not particularly limited, and may be 100% by mole.

The polymer may include a repeating unit other than the repeating unit represented by Formula (A), the repeating unit represented by Formula (B), and the repeating unit represented by Formula (C).

A weight-average molecular weight of the polymer is not particularly limited, but is preferably 10,000 to 1,000,000, and more preferably 50,000 to 500,000 from the viewpoint that the effect of the present invention is more excellent.

In the present specification, the weight-average molecular weight of the polymer is measured by the following device and conditions.
Measuring device: Trade name “HLC-8420GPC” (manufactured by Tosoh Corporation)
Columns: Three columns of TOSOH TSKgel Super AWM-H (manufactured by Tosoh Corporation) connected
Measurement temperature: 40° C.
Eluent: N-Methylpyrrolidone, lithium bromide 10 mM, sample concentration 0.1% to 0.2% by mass
Flow rate: 0.5 mL/min
Detector: UV-VIS detector (product name “UV-8420”, manufactured by Tosoh Corporation)
Molecular weight: Expressed in terms of standard polystyrene

A glass transition temperature of the polymer is not particularly limited, but is preferably 5° C. or higher, more preferably 10° C. or higher, still more preferably 20° C. or higher, and particularly preferably 30° C. or higher from the viewpoint that the shape characteristics of a film including the polymer are more excellent. An upper limit thereof is not particularly limited, but is preferably 60° C. or lower, and more preferably 50° C. or lower from the viewpoint of handleability.

The glass transition temperature can be measured by a dynamic mechanical analysis (DMA) method using a dynamic viscoelasticity measuring device (Rheogel-E4000, manufactured by UBM Co., Ltd.). Specifically, a plate-like sample having a thickness of 0.2 mm, a width of 5 mm, and a length of 10 mm is manufactured using a polymer to be measured, the obtained sample is subjected to sweeping at a temperature of −50 to 150° C., and subjected to a dynamic viscoelasticity measurement with a period of applying stress being 1 Hz, and a temperature at which a maximum tan δ value is exhibited is defined as the glass transition temperature.

The polymer can be synthesized by a known method.

An example of the polymer is shown below. Hereinafter, the structural formula of each repeating unit included in the polymer will be exemplified.

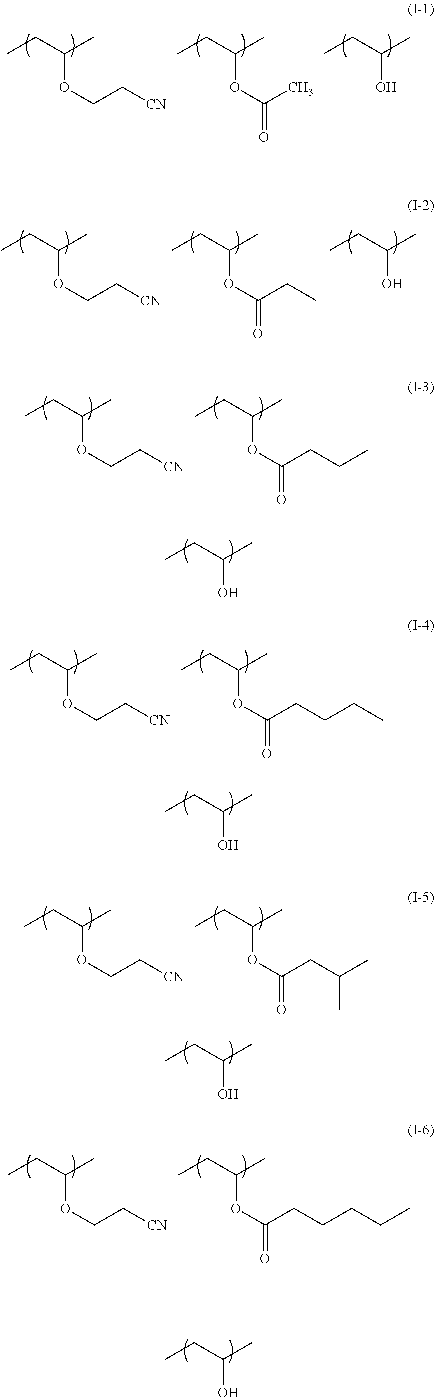

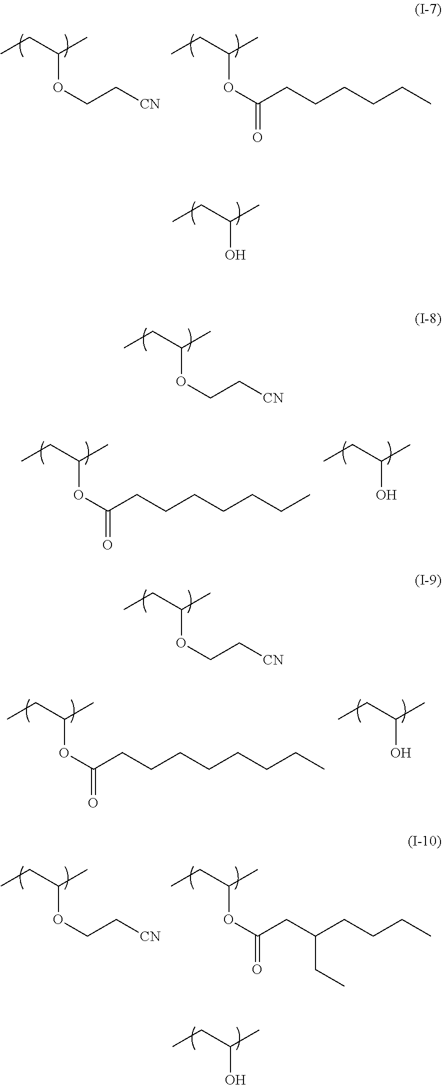

### <Composition>

The composition of an embodiment of the present invention includes the above-described polymer and a cyano group-containing compound different from the polymer.

The description of the polymer is as described above.

A content of the polymer in the composition is not particularly limited, but is preferably 1% to 99% by mass, and more preferably 50% to 95% by mass with respect to the total mass of the composition; from the viewpoint of suppressing the occurrence of wrinkles in a film formed of the composition, the content is still more preferably 60% to 95% by mass; and from the viewpoint of a small change in relative permittivity before and after the exposure of the composition to a high-temperature and high-humidity environment, the content is particularly preferably more than 70% by mass and 95% by mass or less, and most preferably 80% to 95% by mass.

The cyano group-containing compound has a cyano group, and is not particularly limited in structure as long as it is a compound different from the above-described polymer.

The cyano group-containing compound may be a low-molecular-weight compound having no repeating unit, or a high-molecular-weight compound having a repeating unit.

From the viewpoint that the relative permittivity of the composition is more excellent, it is preferable that the cyano group-containing compound has a cyanoethyl group (CN—C₂H₅-*; * represents a bonding position).

A molecular weight of the cyano group-containing compound is not particularly limited, but is preferably 2,000 or less. A lower limit thereof is not particularly limited, but is preferably 100 or more.

The cyano group-containing compound is preferably a compound which is in a liquid state at 20° C.

A cyano group content in the cyano group-containing compound is not particularly limited, but is preferably 1 to 30 mmol/g, and more preferably 5 to 20 mmol/g from the viewpoint that the relative permittivity of the composition is more excellent.

Furthermore, the cyano group content can be calculated from the following expression based on the molar mass of the cyano group-containing compound and the number of cyano groups (number of CNs).

Cyano group content={1/(Molar mass of cyano group-containing compound)}×number of CNs×1,000

As the cyano group-containing compound, a compound represented by Formula (1) is preferable from the viewpoint that the relative permittivity of the composition is more excellent.

(CN—CH₂CH₂)ₙ-L Formula (1)

L represents an n-valent linking group.

The n-valent linking group represented by L is not particularly limited, and examples thereof include an aliphatic hydrocarbon group, an aromatic hydrocarbon group, a heterocyclic group, —O—, —C(═O)—O—, —C(═O)—, —NH—, —S—, and a group obtained by combining these groups.

n represents an integer of 1 to 50. n is preferably 2 to 40, and more preferably 3 to 30.

Furthermore, the compound represented by Formula (1) is also represented by “L-(CH₂CH₂—CN)ₙ”.

As the n-valent linking group, a residue obtained by removing a hydrogen atom from a hydroxyl group in a compound selected from the group consisting of a sugar compound and a sugar alcohol is preferable.

The sugar compound may be any one of a monosaccharide or a polysaccharide.

Examples of the sugar compound include sucrose, sorbitol, raffinose, cyclodextrin, cellobiose, glucose, galactose, arabinose, xylose, maltose, cellobiose, isomaltose, lactose, sucrose, and fructose.

Examples of the sugar alcohol include sorbitol, mannitol, arabitol, and xylitol.

Furthermore, the structural formulae of the cyano group-containing compounds in a case where the n-valent linking groups are a residue obtained by removing a hydrogen atom from a hydroxyl group of sucrose, a residue obtained by removing a hydrogen atom from a hydroxyl group of sorbitol, and a residue obtained by removing a hydrogen atom from a hydroxyl group of raffinose are shown below in order from the left.

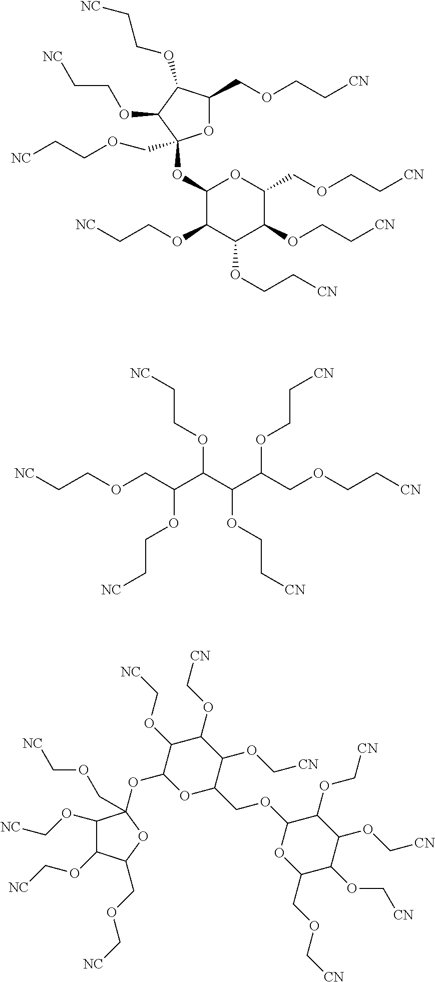 [SMILES: N#CCCOC[C@H]1O[C@@](COCCC#N)(O[C@H]2O[C@H](COCCC#N)[C@@H](OCCC#N)[C@H](OCCC#N)[C@H]2OCCC#N)[C@@H](OCCC#N)[C@@H]1OCCC#N ; N#CCCOCC(OCCC#N)C(OCCC#N)C(OCCC#N)C(COCCC#N)OCCC#N ; N#CCOCC1OC(OCC2OC(OC3(COCC#N)OC(COCC#N)C(OCC#N)C3OCC#N)C(OCC#N)C(OCC#N)C2OCC#N)C(OCC#N)C(OCC#N)C1OCC#N]

As the cyano group-containing compound, cyanoethyl sucrose represented by the leftmost structural formula in the structural formulae is preferable.

A content of the cyano group-containing compound in the composition is not particularly limited, but is preferably 1% to 99% by mass, and more preferably 5% to 50% by mass with respect to the total mass of the composition; from the viewpoint of suppressing the occurrence of wrinkles in a film formed of the composition, the content is still more preferably 5% to 40% by mass; and from the viewpoint of a small change in relative permittivity before and after the exposure of the composition to a high-temperature and high-humidity environment, the content is particularly preferably 5% by mass or more and less than 30% by mass, and most preferably 5% to 20% by mass.

The total content of the polymer and the cyano group-containing compound in the composition is not particularly limited, but from the viewpoint that the relative permittivity of the composition is more excellent, the total content is preferably 80% by mass or more, and more preferably 90% by mass or more with respect to the total mass of the composition. An upper limit of the total content is not particularly limited, and examples thereof include 100% by mass.

A content ratio between the polymer and the cyano group-containing compound in the composition is not particularly limited, but a mass ratio of the content of the polymer to the content of the cyano group-containing compound is preferably 0.5 to 40, and more preferably 3 to 30.

The composition may include a compound other than the above-described polymer and cyano group-containing compound.

Examples of the other compounds include dielectric polymers other than the above-described polymer and cyano group-containing compound. Examples of the other dielectric polymers include fluorine-based polymers such as polyvinylidene fluoride, a vinylidene fluoride-tetrafluoroethylene copolymer, a vinylidene fluoride-trifluoroethylene copolymer, a polyvinylidene fluoride-trifluoroethylene copolymer, and a polyvinylidene fluoride-tetrafluoroethylene copolymer.

In addition, examples of the other compounds also include viscosity imparting agents such as a rosin ester, a rosin, a terpene, a terpene phenol, and a petroleum resin.

Examples of the other components also include a solvent. Examples of the solvent include water and an organic solvent.

Furthermore, it is preferable that the composition does not substantially include a solvent. The expression “the solvent is not substantially included” means that the content of the solvent with respect to the total mass of the composition is 1% by mass or less.

A glass transition temperature of the composition is not particularly limited, but is preferably 5° C. or higher, more preferably 10° C. or higher, still more preferably 20° C. or higher, and particularly preferably 30° C. or higher from the viewpoint that the shape characteristics of a film including the composition are more excellent. An upper limit thereof is not particularly limited, but is preferably 60° C. or lower, and more preferably 50° C. or lower from the viewpoint of handleability.

A method for measuring the glass transition temperature of the composition is the same as the method for measuring the glass transition temperature of the polymer.

### <Piezoelectric Composite Material>

The piezoelectric composite material of an embodiment of the present invention includes the polymer and piezoelectric particles.

The description of the polymer is as described above.

A content of the polymer in the piezoelectric composite material is not particularly limited, but is preferably 1% to 50% by mass, and more preferably 2% to 30% by mass with respect to the total mass of the piezoelectric composite material.

It is preferable that the piezoelectric particles are dispersed in the polymer.

As the piezoelectric particles, ceramics particles having a perovskite-type or wurtzite-type crystal structure are preferable.

Examples of the material constituting the piezoelectric particles include lead zirconate titanate (PZT), lead lanthanum zirconate titanate (PLZT), barium titanate (BaTiO₃), zinc oxide (ZnO), and a solid solution (BFBT) of barium titanate and bismuth ferrite (BiFe₃).

The particle diameter of the piezoelectric particles may be appropriately selected depending on the application of the piezoelectric composite material. The particle diameters of the piezoelectric particles are preferably 1 to 10 μm.

A content of the piezoelectric particles in the piezoelectric composite material is not particularly limited, but is preferably 30% to 99% by mass, and more preferably 50% to 95% by mass with respect to the total mass of the piezoelectric composite material.

A volume fraction of the piezoelectric particles in the piezoelectric composite material is not particularly limited, but is preferably 30% to 80% by volume, and more preferably 50% to 80% by volume with respect to a total volume of the piezoelectric composite material.

A total content of the polymer and the piezoelectric particles in the piezoelectric composite material is not particularly limited, but the total content is preferably 80% by mass or more, and more preferably 90% by mass or more with respect to the total mass of the piezoelectric composite material. An upper limit of the total content is not particularly limited, and examples thereof include 100% by mass.

A content ratio of the polymer to the piezoelectric particles in the piezoelectric composite material is not particularly limited, but a mass ratio of the content of the piezoelectric particles to the content of the polymer is preferably 1 to 30, and more preferably 3 to 20.

The piezoelectric composite material may include a compound other than the above-described polymer and piezoelectric particles.

Examples of the other compounds include the above-described cyano group-containing compound and other dielectric polymers.

In addition, examples of the other compounds also include viscosity imparting agents such as a rosin ester, a rosin, a terpene, a terpene phenol, and a petroleum resin.

### <Piezoelectric Film>

The piezoelectric film of an embodiment of the present invention includes a piezoelectric layer including a piezoelectric composite material, and electrode layers provided on both surfaces of the piezoelectric layer.

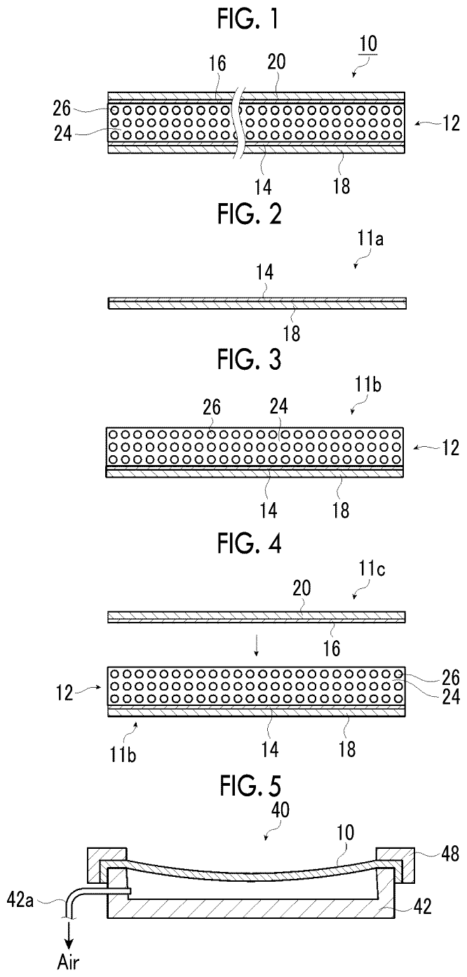

FIG. 1 shows a cross-sectional view conceptually showing an example of the piezoelectric film of the embodiment of the present invention.

As shown in FIG. 1, a piezoelectric film 10 of the embodiment of the present invention includes a piezoelectric layer 12 which is a sheet-like material, a first electrode layer 14 laminated on one surface of the piezoelectric layer 12, a first protective layer 18 laminated on the first electrode layer 14, a second electrode layer 16 laminated on the other surface of the piezoelectric layer 12, and a second protective layer 20 laminated on the second electrode layer 16.

The first electrode layer 14 and the second electrode layer 16 are provided to apply a voltage to the piezoelectric layer 12 (piezoelectric film 10).

The region sandwiched between the first electrode layer 14 and the second electrode layer 16 expands and contracts according to the applied voltage.

Hereinafter, each member included in the piezoelectric film 10 will be described in detail.

### (Piezoelectric Layer)

The piezoelectric layer 12 includes the above-described piezoelectric composite material. More specifically, as shown in FIG. 1, it is preferable that the piezoelectric particles 26 are dispersed in a polymer matrix 24 including a polymer in the piezoelectric layer 12.

The piezoelectric composite material is as described above.

A content of the piezoelectric composite material in the piezoelectric layer 12 is not particularly limited, but is preferably 80% by mass or more, and more preferably 90% by mass or more with respect to the total mass of the piezoelectric layer. An upper limit thereof is not particularly limited, but examples thereof include 100% by mass.

A volume fraction of the piezoelectric particles in the piezoelectric layer 12 is not particularly limited, but is preferably 30% to 80% by volume, and more preferably 50% to 80% by volume with respect to the total volume of the piezoelectric layer.

A content ratio of the polymer to the piezoelectric particles in the piezoelectric layer 12 is not particularly limited, but a mass ratio of the content of the piezoelectric particles to the content of the polymer is preferably 1 to 30, and more preferably 3 to 20.

In addition, a thickness of the piezoelectric layer 12 is not limited, and may be appropriately set according to the size of the piezoelectric film, the use of the piezoelectric film, the characteristics required for the piezoelectric film, and the like.

The thickness of the piezoelectric layer 12 is not particularly limited, but is preferably 8 to 300 μm, and more preferably 8 to 40 μm from the viewpoint of achieving both ensuring of the rigidity of the piezoelectric film and moderate elasticity.

It is preferable that the piezoelectric layer 12 is subjected to a polarization treatment (poling) in the thickness direction.

### (Electrode Layer)

The material for forming the first electrode layer 14 and the second electrode layer 16 is not limited, and various conductors can be used. Examples of the forming material include metals such as carbon, palladium, iron, tin, aluminum, nickel, platinum, gold, silver, copper, titanium, chromium, and molybdenum, alloys thereof, laminates and composites of these metals and alloys, and indium tin oxide. Alternatively, examples of the forming material also include conductive polymers such as polyethylene dioxythiophene-polystyrene sulfonic acid (PEDOT/PPS).

Among these, as the material for forming the first electrode layer 14 and the second electrode layer 16, copper, aluminum, gold, silver, platinum, or indium tin oxide is preferable. Among these, copper is more preferable from the viewpoints of conductivity, cost, flexibility, and the like.

The thicknesses of the first electrode layer 14 and the second electrode layer 16 are not particularly limited. In addition, the thicknesses of the first electrode layer 14 and the second electrode layer 16 may basically be the same as or different from each other.

In the piezoelectric film 10, it is suitable that a product of the thickness and the Young's modulus of the first electrode layer 14 and the second electrode layer 16 is less than a product of the thickness and the Young's modulus of the first protective layer 18 and the second protective layer 20 from the viewpoint that the flexibility is not considerably impaired.

For example, in a combination in which the first protective layer 18 and the second protective layer 20 are made of PET (Young's modulus: about 6.2 GPa) and the first electrode layer 14 and the second electrode layer 16 are made of copper (Young's modulus: about 130 GPa), in a case where the thickness of the first protective layer 18 and the second protective layer 20 is assumed to be 25 μm, the thickness of the first electrode layer 14 and the second electrode layer 16 is preferably 1.2 μm or less, more preferably 0.3 μm or less, and still more preferably 0.1 μm or less.

### (Protective Layer)

The first protective layer 18 and the second protective layer 20 cover the first electrode layer 14 and the second electrode layer 16, while imparting appropriate rigidity and mechanical strength to the piezoelectric layer 12. That is, the piezoelectric layer 12 consisting of the polymer matrix 24 and the piezoelectric particles 26 in the piezoelectric film 10 exhibits extremely excellent flexibility under bending deformation at a slow vibration, but may have insufficient rigidity or mechanical strength depending on the applications. As a compensation for this, the piezoelectric film 10 is provided with the first protective layer 18 and the second protective layer 20.

The first protective layer 18 and the second protective layer 20 are not particularly limited, and various sheet-like materials can be used, and suitable examples thereof include various resin films.

Among these, from the viewpoint of excellent mechanical characteristics and heat resistance, a resin film consisting of polyethylene terephthalate (PET), polypropylene (PP), polystyrene (PS), polycarbonate (PC), polyphenylene sulfide (PPS), polymethyl methacrylate (PMMA), polyetherimide (PEI), polyimide (PI), polyethylene naphthalate (PEN), triacetyl cellulose (TAC), a cyclic olefin-based resin, and the like is preferable.

The thicknesses of the first protective layer 18 and the second protective layer 20 are not particularly limited. In addition, the thicknesses of the first protective layer 18 and the second protective layer 20 are basically the same as each other, but may be different from each other.

From the viewpoint of achieving both ensuring of the rigidity and moderate elasticity, the thicknesses of the first protective layer 18 and the second protective layer 20 are preferably equal to or less than twice the thickness of the piezoelectric layer 12.

For example, in a case where the thickness of the piezoelectric layer 12 is 50 μm and the first protective layer 18 and the second protective layer 20 consist of PET, the thicknesses of the first protective layer 18 and the second protective layer 20 are preferably 100 μm or less, more preferably 50 μm or less, and still more preferably 25 μm or less.

In the present invention, the piezoelectric film may include, in addition to the above-described respective layers, for example, a bonding layer for bonding the electrode layer and the piezoelectric layer to each other, and a bonding layer for bonding the electrode layer and the protective layer to each other.

The bonding agent may be an adhesive or a pressure sensitive adhesive. In addition, the same material as the polymer material obtained by removing the piezoelectric particles from the piezoelectric layer, that is, the matrix can also be suitably used as the bonding agent. Furthermore, the bonding layer may be provided on both the first electrode layer side and the second electrode layer side, or may be provided on only one of the first electrode layer side and the second electrode layer side.

In the piezoelectric film of the embodiment of the present invention, it is preferable that the maximal value of the loss tangent (tan δ) at a frequency of 1 Hz according to a dynamic viscoelasticity measurement is present at room temperature, and it is more preferable that the maximal value at which the loss tangent is 0.1 or more is present at room temperature.

In this manner, even in a case where the piezoelectric film is subjected to bending deformation at a slow vibration of less than or equal to a few Hz from the outside, since the strain energy can be effectively diffused to the outside as heat, the occurrence of cracks on an interface between the matrix and the piezoelectric particle can be prevented.

In the piezoelectric film, it is preferable that the storage elastic modulus (E′) at a frequency of 1 Hz according to the dynamic viscoelasticity measurement is 10 to 30 GPa at 0° C., and 1 to 10 GPa at 50° C. Furthermore, the same also applies to the conditions for the piezoelectric layer.

In such a manner, the piezoelectric film 10 may have large frequency dispersion in the storage elastic modulus (E′) at normal temperature. That is, the piezoelectric film can be rigid with respect to a vibration of 20 Hz to 20 kHz, and can be flexible with respect to a vibration of less than or equal to a few Hz.

In addition, in the piezoelectric film, it is preferable that the product of the thickness and the storage elastic modulus (E′) at a frequency of 1 Hz according to the dynamic viscoelasticity measurement is in a range of 1.0×10⁵ to 2.0×10⁶ N/m at 0° C., and is in a range of 1.0×10⁵ to 1.0×10⁶ N/m at 50° C. Furthermore, the same also applies to the conditions for the piezoelectric layer.

In this manner, the piezoelectric film may have moderate rigidity and mechanical strength within a range not impairing the flexibility and the acoustic characteristics.

Furthermore, in the piezoelectric film, it is preferable that the loss tangent (Tan δ) at a frequency of 1 kHz at 25° C. is 0.05 or more in a master curve obtained from the dynamic viscoelasticity measurement. The same also applies to the conditions for the piezoelectric layer.

In this manner, the frequency characteristics of a speaker including the piezoelectric film are smooth, so that an amount of change in acoustic quality in a case where the lowest resonance frequency f₀ is changed according to a change in curvature of the speaker can be decreased.

Furthermore, in the present invention, the storage elastic modulus (Young's modulus) and the loss tangent of the piezoelectric film, the piezoelectric layer, and the like may be measured by known methods. As an example, the measurement may be performed using a dynamic viscoelasticity measuring device DMS6100 (manufactured by SII Nanotechnology Inc.).

Examples of the measurement conditions include conditions with a measurement frequency of 0.1 Hz to 20 Hz (0.1 Hz, 0.2 Hz, 0.5 Hz, 1 Hz, 2 Hz, 5 Hz, 10 Hz, and 20 Hz), a measurement temperature of −50° C. to 150° C., a temperature rising rate of 2° C./min (in a nitrogen atmosphere), a sample size of 40 mm×10 mm (including the clamped region), and a chuck-to-chuck distance of 20 mm.

### (Method for Producing Piezoelectric Film)

Hereinafter, an example of the method for producing the piezoelectric film 10 will be described with reference to FIGS. 2 to 4.

First, as shown in FIG. 2, a sheet-like material 11a in which the first electrode layer 14 has been formed on a surface of the first protective layer 18 is prepared. Furthermore, as conceptually shown in FIG. 4, a sheet-like material 11c in which the second electrode layer 16 has been formed on a surface of the second protective layer 20 is prepared.

The sheet-like material 11a may be manufactured by forming a copper thin film or the like as the first electrode layer 14 on a surface of the first protective layer 18 by vacuum vapor deposition, sputtering, plating, or the like. Similarly, the sheet-like material 11c may be manufactured by forming a copper thin film or the like as the second electrode layer 16 on a surface of the second protective layer 20 by vacuum vapor deposition, sputtering, plating, or the like.

Alternatively, a commercially available sheet-like material in which a copper thin film or the like is formed on a protective layer may be used as the sheet-like material 11a and/or the sheet-like material 11c.

The sheet-like material 11a and the sheet-like material 11c may be the same as or different from each other.

Next, as shown in FIG. 3, a coating material (coating composition) serving as the piezoelectric layer 12 is applied onto the first electrode layer 14 of the sheet-like material 11a, and then cured to form the piezoelectric layer 12. In this manner, a laminate 11b in which the sheet-like material 11a and the piezoelectric layer 12 are laminated is manufactured.

Examples of the method of forming the piezoelectric layer 12 include a method of using a coating material.

In this method, first, the above-described polymer is dissolved in an organic solvent, and further, piezoelectric particles such as PZT particles are added thereto and stirred to prepare a coating material.

The organic solvent is not particularly limited, and various organic solvents such as dimethylformamide (DMF), methyl ethyl ketone (MEK), and cyclohexanone can be used.

In a case where the sheet-like material 11a is set up and the coating material is prepared, the coating material is cast (applied) onto the sheet-like material 11a, and the organic solvent is evaporated and dried. In this manner, as shown in FIG. 3, the laminate 11b having the first electrode layer 14 on the first protective layer 18 and including the piezoelectric layer 12 laminated on the first electrode layer 14 is manufactured.

A method for casting the coating material is not particularly limited, and examples thereof include known methods (coating devices) such as a bar coater, a slide coater, and a doctor knife.

In addition, in a case where the polymer is a polymer that can be heated and melted, the laminate 11b as shown in FIG. 3 may be manufactured by heating and melting the polymer to produce a melt obtained by adding piezoelectric particles to the melt, extruding the melt in a sheet shape onto the sheet-like material 11a shown in FIG. 2 by performing extrusion molding or the like, and cooling.

After forming the piezoelectric layer 12, a calendering treatment may be performed as necessary. The calendaring treatment may be performed once or a plurality of times.

As is well known, the calendering treatment is a treatment in which a surface to be treated is pressed while being heated by a heating press and a heating roller to flatten the surface.

Next, the piezoelectric layer 12 of the laminate 11b having the first electrode layer 14 on the first protective layer 18 and including the piezoelectric layer 12 formed on the first electrode layer 14 is subjected to a polarization treatment (poling). The polarization treatment for the piezoelectric layer 12 may be performed before the calendering treatment, but it is preferable that the polarization treatment is performed after the calendering treatment.

A method for performing a polarization treatment on the piezoelectric layer 12 is not particularly limited, and a known method can be used. Examples of the method include electric field poling in which a direct current electric field is directly applied to a target to be subjected to the polarization treatment. Furthermore, in a case of performing the electric field poling, the second electrode layer 16 is formed before the polarization treatment, and thus, the electric field poling treatment may be performed using the first electrode layer 14 and the second electrode layer 16.

In addition, in the piezoelectric film 10 of the embodiment of the present invention, it is preferable that the polarization treatment is performed in the thickness direction instead of the plane direction of the piezoelectric layer 12.

Next, as shown in FIG. 4, the sheet-like material 11c which has been prepared in advance is laminated on the piezoelectric layer 12 side of the laminate 11b that has been subjected to the polarization treatment, such that the second electrode layer 16 faces the piezoelectric layer 12.

Furthermore, the piezoelectric film 10 as shown in FIG. 1 is manufactured by subjecting the laminate to a thermal compression bonding using a heating roller or the like such that the first protective layer 18 and the second protective layer 20 are sandwiched, and bonding the laminate 11b to the sheet-like material 11c.

Alternatively, the piezoelectric film 10 may be manufactured by bonding and preferably further compression-bonding the laminate 11b and the sheet-like material 11c to each other using an adhesive. As the adhesive in this case, the same material as the matrix of the piezoelectric layer 12 can be used.

Furthermore, the piezoelectric film 10 may be produced using the cut sheet-like material 11a and the cut sheet-like material 11c, or may be produced by roll-to-roll.

The manufactured piezoelectric film 10 may be cut into a desired shape according to various applications.

A conceptual view showing an example of a flat plate type piezoelectric speaker using the piezoelectric film 10 is shown in FIG. 5.

A piezoelectric speaker 40 is a flat plate type piezoelectric speaker using the piezoelectric film 10 as a vibration plate that converts an electrical signal into vibration energy. Furthermore, the piezoelectric speaker 40 can also be used as a microphone, a sensor, or the like.

The piezoelectric speaker 40 is configured to have the piezoelectric film 10, a case 42, and a pressing lid 48.

The case 42 is a cylindrical housing formed of plastic or the like and having one surface that is open. A pipe 42a to be inserted into the case 42 is provided on a side surface of the case 42.

In addition, the pressing lid 48 is a frame having a substantially L-shaped cross section, and is inserted into the open surface of the case 42 and fitted thereto.

In the piezoelectric speaker 40, the opening surface of the case 42 is airtightly blocked with the piezoelectric film 10 by covering the case 42 with the piezoelectric film 10 such that the opening surface is closed, and fitting the pressing lid 48 to the case 42 from above the piezoelectric film 10. Furthermore, an O-ring or the like for maintaining airtightness may be provided between the upper surface of the side wall of the case 42 and the piezoelectric film 10, as necessary.

In this state, the air inside the case 42 is released from the pipe 42a to maintain the piezoelectric film 10 in a concave state as shown in FIG. 5. On the contrary, the piezoelectric film 10 may be maintained in a convex state by introducing air into the case 42 from the pipe 42a.

In the piezoelectric speaker 40, in a case where the piezoelectric film 10 is stretched in the in-plane direction due to the application of a driving voltage to the first electrode layer 14 and the second electrode layer 16, the piezoelectric film 10 in a concave state due to decompression moves downward in order to absorb the stretched part.

On the contrary, in a case where the piezoelectric film 10 is contracted in the in-plane direction due to the application of a driving voltage to the first electrode layer 14 and the second electrode layer 16, the piezoelectric film 10 in a concave state moves upward in order to absorb the contracted part.

The piezoelectric speaker 40 generates a sound by the vibration of the piezoelectric film 10.

### <Piezoelectric Element>

The piezoelectric element of an embodiment of the present invention includes the above-described piezoelectric film.

The piezoelectric element may have one layer of the piezoelectric film or may have a plurality of layers of the piezoelectric films. In a case where a plurality of layers of the piezoelectric films are laminated, the number of layers of the piezoelectric films may be 2 or may be 4 or more.

In addition, the piezoelectric film may be folded and laminated.

In the piezoelectric element, a power supply is connected to the first electrode layer and the second electrode layer of each piezoelectric film to apply a driving voltage for stretching and contracting the piezoelectric film, that is, to supply driving power.

The power supply is not particularly limited, and may be a direct current power supply or an alternating current power supply. In addition, as the driving voltage, a driving voltage capable of suitably driving the piezoelectric films may be suitably set in accordance with the thickness, forming material, and the like of the piezoelectric layer in the piezoelectric film.

A method for leading out the electrode from the first electrode layer and the second electrode layer is not particularly limited, and various known methods can be used.

Examples thereof include a method of connecting a conductor such as a copper foil to the first electrode layer and the second electrode layer, and leading-out an electrode to the outside, and a method of forming through-holes in the first protective layer and the second protective layer with a laser or the like and filling the through-holes with a conductive material to lead-out an electrode to the outside.

Suitable examples of the method for extracting an electrode include the method described in JP2014-209724A and the method described in JP2016-015354A.

In addition, in a case where the piezoelectric element has a configuration in which the piezoelectric film is folded and laminated, it is preferable that the piezoelectric film of the outermost layer has a protruding portion that protrudes outward in the plane direction from the laminated portion in which the piezoelectric film is laminated, and a connecting portion for connecting the first electrode layer and the second electrode layer with the power supply is formed in the protruding portion. Furthermore, a method for connecting the electrode layer and the wiring line in the protruding portion is not particularly limited, and various known methods can be used.

The piezoelectric film or piezoelectric element of the embodiment of the present invention may be attached to a vibration plate to be used as an electroacoustic transducer. In the electroacoustic transducer, the piezoelectric film is used as a so-called exciter which exhibits piezoelectricity in response to an applied voltage to vibrate a vibration plate.

It is preferable that the vibration plate has flexibility that allows the vibration plate to be rolled up. Furthermore, in the present invention, the expression of having flexibility has the same definition as an expression of having flexibility in general interpretation, and indicates being bendable and flexible, specifically, being bendable and stretchable without causing breakage and damage.

The vibration plate is not particularly limited, and various sheet-like materials (plate-like materials and films) can be used.

Examples thereof include resin films consisting of polyethylene terephthalate (PET), polypropylene (PP), polystyrene (PS), polycarbonate (PC), polyphenylene sulfide (PPS), polymethylmethacrylate (PMMA), and polyetherimide (PEI), polyimide (PI), polyethylene naphthalate (PEN), triacetyl cellulose (TAC), cyclic olefin-based resins, or the like, foamed plastic consisting of expanded polystyrene, expanded styrene, expanded polyethylene, or the like, veneer boards, cork boards, leathers such as cowhide, various paperboards such as carbon sheets and Japanese paper, various corrugated cardboard materials obtained by bonding other paperboards to one or both surfaces of a corrugated paperboard, various metals such as stainless steel, aluminum, copper, and nickel, and thin metal films consisting of various alloys.

In addition, the vibration plate may be a composite material obtained by bonding a film-like material consisting of these materials.

Moreover, as the vibration plate, a display device such as an organic electroluminescence (organic light emitting diode (OLED)) display, a liquid crystal display, a micro light emitting diode (LED) display, and an inorganic electroluminescence display, a screen for a projector, and the like can be suitably used as long as they have flexibility.

A bonding layer may be disposed between the piezoelectric film or the piezoelectric element and the vibration plate.

A thickness of the bonding layer is not particularly limited, and a thickness at which a sufficient bonding force (an adhesive force, a pressure sensitive adhesive force) can be obtained may be appropriately set depending on the material of the bonding layer.

The thickness of the bonding layer after bonding is preferably 0.1 to 50 μm, more preferably 0.1 to 30 μm, and still more preferably 0.1 to 10 μm.

Various known bonding layers can be used.

Therefore, the bonding layer may be a layer formed of an adhesive which has fluidity in a case of bonding and then is to be a solid, a layer formed of a pressure sensitive adhesive which is a gel-like (rubber-like) soft solid in a case of bonding and the gel-like state does not change thereafter, or a layer formed of a material having characteristics of both the adhesive and the pressure sensitive adhesive. Furthermore, the adhesive (pressure sensitive adhesive) may be any of a moisture-curing adhesive, a thermoplastic adhesive, or a thermosetting adhesive. In addition, a double-sided tape or a pressure sensitive adhesive sheet may be used as the bonding layer.

### EXAMPLES

Hereinafter, the present invention will be described in more detail with reference to specific examples of the present invention. Furthermore, the present invention is not limited to Examples, and the materials, the used amounts, the proportions, the treatment contents, the treatment procedures, and the like shown in Examples below can be appropriately changed within a range not departing from the scope of the present invention.

### Synthesis Example 1

CR-V (manufactured by Shin-Etsu Chemical Co., Ltd.) (11.2 g) and methyl ethyl ketone (MEK) (54 mL) were added to a 500 mL three-neck flask, and the obtained reaction solution was stirred. Then, sodium hydrogen carbonate (16.9 g) and 4-dimethylaminopyridine (DMAP) (0.035 g) were added to the reaction solution, and the obtained reaction solution was stirred. Next, a solution consisting of acetic anhydride (16.0 g) and MEK (13.4 mL) was added dropwise to the reaction solution, and the obtained reaction solution was heated to 80° C. After performing the reaction for 2 hours, the reaction solution was cooled to 60° C., MEK (112 mL) was added to the reaction solution, and then water (14 mL) was added dropwise thereto. Thereafter, water (112 mL) was further added to the obtained reaction solution, the organic phase was extracted, and the obtained organic phase was dried over magnesium sulfate. Thereafter, the solvent was distilled off from the dried organic phase with an evaporator to obtain an MEK solution (42.4 g) including a polymer (polymer 1) used in Example 1. Furthermore, the concentration of the polymer in the solution was 25.2% by mass.

### Synthesis Example 2

An MEK solution (42.4 g) including a polymer (polymer 2) used in Example 2 was obtained according to the same procedure as in Synthesis Example 1, except that the acetic anhydride (16.0 g) of Synthesis Example 1 was changed to propionic anhydride (16.0 g). Furthermore, the concentration of the polymer represented by Formula (I-2) in the solution was 25.2% by mass.

Moreover, other polymers used in Examples which will be described later were synthesized with reference to the above-described Synthesis Examples. Specifically, the number of carbon atoms of R in the repeating unit represented by Formula (B) and the content of the repeating unit were adjusted by using a predetermined amount of a predetermined raw material instead of the acetic anhydride.

### Example 1

An MEK solution (3 g) including the polymer 1 produced in Synthesis Example 1 was added to a petri dish, the petri dish was heated to 100° C. on a hot plate, and then dried at 100° C. for 6 hours under reduced pressure. The obtained film was peeled from the petri dish to take out a single film.

### Examples 2 to 10 and Comparative Examples 1 and 2

An MEK solution (concentration of polymer: 25.2% by mass) including a polymer shown in Table 1 which will be described later was prepared, and a single film was produced according to the same procedure as in Example 1.

### <Evaluations>

### (Relative Permittivity)

A striped test piece having a size of 2 cm×4 cm was prepared from each of the single films manufactured in each of Examples and Comparative Examples.

A relative permittivity Fr of the striped test piece was measured with an LCR meter. Furthermore, the measurement temperature was 25° C. and the measurement frequency was 1 kHz. The measurement results are shown in Table 1.

### (Moisture Resistance Test)

A striped test piece having a size of 2 cm×4 cm was prepared from each of the single films manufactured in each of Examples and Comparative Examples.

This striped test piece was left to stand in an environment of a humidity of 80% and a temperature of 60% for 1 hour, and then a change in relative permittivity and appearance before and after the leaving was examined, and evaluated according to the following standards.

A: No change in relative permittivity and appearance was observed.

B: No change in relative permittivity was observed, but traces of the fold and the like remained.

C: A change in relative permittivity was observed.

### (Tg Evaluation)

A glass transition temperature of the polymer was measured by a dynamic viscoelasticity measurement device (Rheogel-E4000, manufactured by UB-M Co., Ltd.) according to a dynamic mechanical analysis (DMA) method. Specifically, a plate-like sample having a thickness of 0.2 mm, a width of 5 mm, and a length of 10 mm was manufactured using a polymer which is a measurement target, and the obtained sample was subjected to sweeping at a temperature of −50 to 150° C. and subjected to a dynamic viscoelasticity measurement with a period of applying stress being 1 Hz, and a temperature at which the maximum tan δ value was exhibited was defined as the glass transition temperature.

### (Shape Evaluation)

The single film manufactured in each of Examples and Comparative Examples was visually observed, and the occurrence of wrinkles was evaluated. In the evaluation, as a result of visual observation, a case where there was no shape defect (occurrence of wrinkles) was evaluated as “A”, a case where there was a slight shape defect was evaluated as “B”, and a case where the occurrence of the shape defect was clearly recognized was evaluated as “C”.

The column of “Polymer” in Table 1 shows the structure of the polymer used in each of Examples and Comparative Examples.

The column of “Type” in the column of “Polymer” shows the type of the polymer used in each of Examples and Comparative Examples. For example, in Example 1, the polymer 1 was used.

The column of “Skeleton” in the column of “Polymer” shows which of Formula (I-1), Formula (I-2), Formula (I-4), Formula (I-6), Formula (I-9), Formula (I-10), Formula (R-1), and Formula (R-2) which will be described later corresponds to the repeating unit included in the polymer used in each of Examples and Comparative Examples.

The columns of “a”, “b”, and “c” in the column of “Polymer” show numerical values of a, b, and c, respectively, in the formulae shown in the column of “Skeleton”. a, b, and c each represent a content (% by mole) of the repeating unit with respect to all repeating units of the polymer.

With regard to Comparative Example 2 in Table 1, since the “Shape evaluation” was “C”, the “Moisture resistance evaluation” was not carried out, and the result is shown as “-” in Table 1.

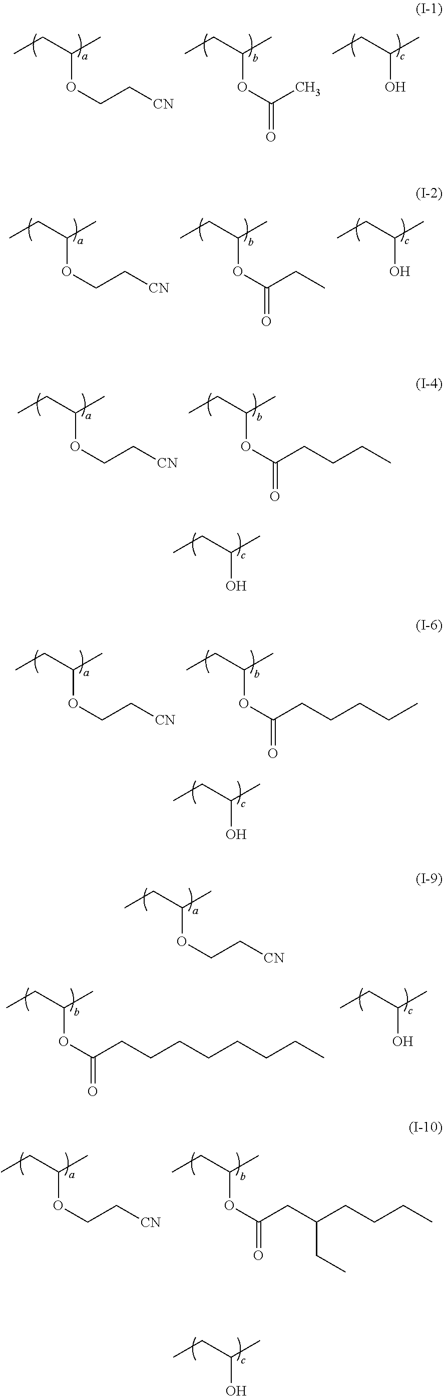

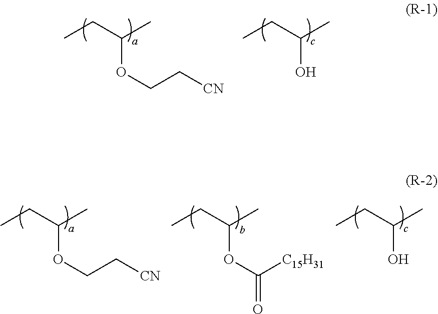

For example, in Table 1, the polymer 1 means a polymer represented by the following formula. That is, the polymer means a polymer in which the content of the repeating unit represented by Formula (A) is 80% by mole, the content of the repeating unit represented by Formula (B), in which R is a methyl group, is 19% by mole, and the content of the repeating unit represented by Formula (C) is 1% by mole.

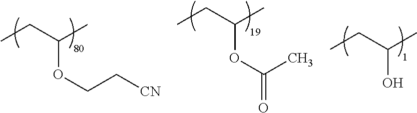

TABLE 1

| | Polymer | | | | | | Evaluation | | | |
|---|---|---|---|---|---|---|---|---|---|---|
| | | | | | | Number of | | Moisture | | |
| | | | | | | carbon | Relative | resistance | Tg | Shape |
| | Type | Skeleton | a | b | c | atoms | permittivity | evaluation | (° C.) | evaluation |
| Example 1 | Polymer 1 | I-1 | 80 | 19 | 1 | 1 | 16 | B | 43 | A |
| Example 2 | Polymer 2 | I-2 | 80 | 20 | 0 | 2 | 16 | A | 40 | A |
| Example 3 | Polymer 3 | I-4 | 80 | 19 | 1 | 4 | 16 | A | 38 | A |
| Example 4 | Polymer 4 | I-6 | 80 | 20 | 0 | 5 | 16 | A | 32 | A |
| Example 5 | Polymer 5 | I-9 | 80 | 19 | 1 | 8 | 16 | A | 30 | A |
| Example 6 | Polymer 6 | I-10 | 80 | 20 | 0 | 8 | 16 | A | 27 | B |
| Example 7 | Polymer 7 | I-2 | 60 | 39 | 1 | 2 | 15 | B | 25 | B |
| Example 8 | Polymer 8 | I-2 | 95 | 4 | 1 | 2 | 18 | A | 35 | A |
| Example 9 | Polymer 9 | I-2 | 85 | 12 | 3 | 2 | 16 | A | 35 | A |
| Example 10 | Polymer 10 | I-2 | 95 | 2 | 3 | 2 | 16 | A | 35 | A |
| Comparative | Polymer C1 | R-1 | 80 | 0 | 20 | — | 16 | C | 34 | A |
| Example 1 | | | | | | | | | | |
| Comparative | Polymer C2 | R-2 | 80 | 17 | 3 | 15 | 15 | — | 2 | C |
| Example 2 | | | | | | | | | | |

As shown in the table, the polymer of the embodiment of the present invention exhibited a predetermined effect.

From aliphatic hydrocarbon group comparison of Examples 1 to 5, it was confirmed that in a case where the number of carbon atoms in the aliphatic hydrocarbon group represented by R in the repeating unit represented by Formula (B) is 2 to 8, the moisture resistance evaluation is more excellent.

From the comparison between Examples 5 and 6, it was confirmed that in a case where the aliphatic hydrocarbon group represented by R in the repeating unit represented by Formula (B) is linear, the shape evaluation is more excellent.

From the comparison between Examples 2 and 7, it was confirmed that in a case where the content of the repeating unit represented by Formula (A) is 70% by mole or more, the relative permittivity and the moisture resistance are more excellent.

### Examples 11 to 19

An MEK solution (concentration of polymer: 25.2% by mass) including a polymer shown in Table 2 which will be described later was prepared, and a single film was manufactured according to the same procedure as in Example 1, using a solution obtained by mixing the MEK solution with the cyano group-containing compound shown in Table 2 which will be described later.

The single film was composed of a polymer and a cyano group-containing compound.

Furthermore, the cyano group-containing compounds used in Table 2 are as follows.
Cyanoethyl sucrose: Manufactured by Shin-Etsu Chemical Co., Ltd., CR-U (cyano group content: 10.4 mmol/g)
Cyanoethyl sorbitol: Synthetic product (see a synthesis method in a latter stage) (cyano group content: 12.0 mmol/g)
Cyanoethyl β-cyclodextrin: Synthetic product (see synthesis method in latter stage) (cyano group content: 9.3 mmol/g)

### (Method for Synthesizing Cyanoethylated Sorbitol)

A 3% sodium hydroxide solution (200 g) was added to and dissolved in sorbitol (30 g), acrylonitrile (150 g) was added to the obtained solution, and the obtained reaction solution was reacted at 40° C. for 4 hours. After completion of the reaction, acetic acid (1.8 g) was added to the obtained reaction solution for neutralization, and the reaction was stopped. Thereafter, the obtained reaction solution was heated to distill off unreacted acrylonitrile. Then, methylene chloride (390 g) was added to the residue for dissolution, water (170 mL) was added thereto, the mixture was stirred and then allowed to stand to separate the liquid, and the water phase was removed. Thereafter, the solvent in the organic phase obtained by the evaporator was distilled off to obtain a composition (70 g) including cyanoethylated sorbitol as a main component.

Cyanoethylated β-cyclodextrin was synthesized according to the same procedure as described above, except that cyclodextrin was used instead of sorbitol as a raw material.

The above-described various evaluations were carried out using the single film obtained above. The results are summarized in Table 2.

In Table 2, the column of “Content (% by mass)” in the column of “Cyano group-containing compound” shows a content (% by mass) of the cyano group-containing compound with respect to the total amount of the single film.

TABLE 2

| | | | | | | | Cyano group-containing | | | | | |
|---|---|---|---|---|---|---|---|---|---|---|---|---|
| | Polymer | | | | | | compound | | Evaluation | | | |
| | | | | | | Number | | Content | | Moisture | | |
| | | | | | | of carbon | | (% by | Relative | resistance | Tg | Shape |
| | Type | Skeleton | a | b | c | atoms | Type | mass) | permittivity | evaluation | (° C.) | evaluation |
| Example | Polymer | I-2 | 80 | 20 | 0 | 2 | Cyanoethyl | 5 | 17 | A | 38 | A |
| 11 | 2 | | | | | | sucrose | | | | | |
| Example | Polymer | I-2 | 80 | 20 | 0 | 2 | Cyanoethyl | 10 | 18 | A | 35 | A |
| 12 | 2 | | | | | | sucrose | | | | | |
| Example | Polymer | I-2 | 80 | 20 | 0 | 2 | Cyanoethyl | 20 | 20 | A | 32 | A |
| 13 | 2 | | | | | | sucrose | | | | | |
| Example | Polymer | I-2 | 80 | 20 | 0 | 2 | Cyanoethyl | 30 | 20 | B | 30 | A |
| 14 | 2 | | | | | | sucrose | | | | | |
| Example | Polymer | I-2 | 80 | 20 | 0 | 2 | Cyanoethyl | 50 | 20 | B | 26 | B |
| 15 | 2 | | | | | | sucrose | | | | | |
| Example | Polymer | I-4 | 80 | 19 | 1 | 4 | Cyanoethyl | 15 | 19 | A | 32 | A |
| 16 | 3 | | | | | | sorbitol | | | | | |
| Example | Polymer | I-6 | 80 | 20 | 0 | 5 | Cyanoethyl | 10 | 19 | A | 30 | A |
| 17 | 4 | | | | | | sorbitol | | | | | |
| Example | Polymer | I-9 | 80 | 19 | 1 | 8 | Cyanoethyl | 5 | 18 | A | 28 | B |
| 18 | 5 | | | | | | sorbitol | | | | | |
| Example | Polymer | I-10 | 80 | 20 | 0 | 8 | Cyanoethyl β- | 10 | 19 | A | 25 | B |
| 19 | 6 | | | | | | cyclodextrin | | | | | |

As shown in Table 2, it was confirmed that an excellent effect is obtained with the composition including the polymer of the embodiment of the present invention and the cyano group-containing compound.

From a comparison between Example 2 and Example 11, it was confirmed that in a case where the cyano group-containing compound is used, the relative permittivity is more excellent.

From a comparison of Examples 11 to 15, it was confirmed that in a case where the content of the cyano group-containing compound is 500 to 40% by mass, the shape evaluation is more excellent. In addition, it was confirmed that in a case where the content of the cyano group-containing compound is 50% to 20% by mass, the moisture resistance evaluation is more excellent.

### <Production of Piezoelectric Film>

The piezoelectric film 10 shown in FIG. 1 was manufactured by the method shown in FIGS. 2 to 4 described above.

First, PZT particles were added to the 25% by mass MEK solution of a predetermined polymer used in Examples and Comparative Examples at the following compositional ratio, and dispersed with a propeller mixer (rotation speed: 2,000 rpm) to prepare a coating material for forming a piezoelectric layer.
PZT Particles: 300 parts by mass
25.2% by mass MEK solution of predetermined polymer: 120 parts by mass

Furthermore, particles obtained by sintering commercially available PZT raw material powder at 1,000° C. to 1,200° C. and then crushing and classifying the sintered powder to have an average particle diameter of 5 μm were used as the PZT particles.

On the other hand, two sheet-like materials (the sheet-like material 11a and the sheet-like material 11c) obtained by subjecting a copper thin film having a thickness of 0.1 μm to vacuum vapor deposition were prepared on a PET film having a thickness of 4 m. That is, in the present example, the first electrode layer 14 and the second electrode layer 16 were copper vapor-deposited thin films having a thickness of 0.1 m, and the first protective layer 18 and the second protective layer 20 were PET films having a thickness of 4 μm.

A coating material for forming the piezoelectric layer 12 was applied onto the copper vapor-deposited thin film (first electrode layer 14) of the sheet-like material (sheet-like material 11a) using a slide coater. Furthermore, the coating material was applied onto the second electrode layer such that the film thickness of the coating film after being dried reached 40 μm.

Next, the coating material which had been applied onto the copper vapor-deposited thin film (first electrode layer 14) was heated and dried on a hot plate at 120° C. to evaporate cyclohexanone. In this manner, a laminate (laminate 11b), in which the first electrode layer 14 made of copper was provided on the first protective layer 18 made of PET and the piezoelectric layer 12 having a thickness of 40 μm was formed thereon, was manufactured.

The piezoelectric layer 12 of the laminate 11b was subjected to a polarization treatment by corona poling. Furthermore, the polarization treatment was performed by applying a direct current voltage of 6 kV between the first electrode layer 14 and the corona electrode at a temperature of the piezoelectric layer 12 set at 100° C. to cause corona discharge.

The sheet-like material 11c was laminated on the laminate 11b which had been subjected to the polarization treatment with the second electrode layer 16 (copper thin film side) facing the piezoelectric layer 12.

Next, the laminate of the laminate 11b and the sheet-like material 11c was subjected to thermal compression bonding at 120° C. using a laminator device to bond the piezoelectric layer 12, the first electrode layer 14, and the second electrode layer 16 to each other, thereby manufacturing a piezoelectric film 10.

### <Manufacture of Piezoelectric Speaker>

A circular test piece having a diameter of 70 mm was cut out from the manufactured piezoelectric film to manufacture a piezoelectric speaker as shown in FIG. 5.

The case was a cylindrical container with one open surface, and a plastic cylindrical container having an opening portion having a diameter of 60 mm and a depth of 10 mm was used.

The piezoelectric film was disposed such that the opening portion of the case was covered, the peripheral portion was fixed with a pressing lid, the air inside the case was exhausted from a pipe, the pressure inside the case was maintained at 0.09 MPa, and the piezoelectric film was curved in a concave shape, thereby manufacturing a piezoelectric speaker.

The piezoelectric film and the piezoelectric element of the embodiments of the present invention are suitably used as, for example: various sensors such as a sound wave sensor, an ultrasonic wave sensor, a pressure sensor, a tactile sensor, a strain sensor, and a vibration sensor (which are useful particularly for an infrastructure examination such as crack detection and a manufacturing site inspection such as foreign matter contamination detection); acoustic devices such as microphones, pickups, speakers, and exciters (as specific applications, noise cancellers (used for cars, trains, airplanes, robots, and the like), artificial voice bands, buzzers to prevent pests and beasts from invading, furniture, wallpaper, photo, helmet, goggles, headrest, signage, robot, and the like are exemplified); haptics used for application to automobiles, smartphones, smart watches, games, and the like; ultrasonic transducers such as ultrasound probe and hydrophones; actuators used for prevention of attachment of water droplets, transportation, agitation, dispersion, polishing, and the like; damping materials (dampers) used for containers, vehicles, buildings, sports equipment such as skis and rackets; and vibration power generator used for application to roads, floors, mattresses, chairs, shoes, tires, wheels, computer keyboards, and the like.

### EXPLANATION OF REFERENCES

10: piezoelectric film
11a, 11c: sheet-like material
11b: laminate
12: piezoelectric layer
14: first electrode layer
16: second electrode layer
18: first protective layer
20: second protective layer
24: polymer matrix
26: piezoelectric particle
40: piezoelectric speaker
42: case
48: frame

What is claimed is:

1. A polymer comprising:
a repeating unit represented by Formula (A); and
a repeating unit represented by Formula (B),
wherein a content of the repeating unit represented by Formula (A) is 60% by mole or more with respect to all repeating units of the polymer,
a content of the repeating unit represented by Formula (B) is 1% to 40% by mole with respect to all repeating units of the polymer, and
the polymer includes no repeating unit represented by Formula (C), or
in a case where the polymer includes the repeating unit represented by Formula (C), a content of the repeating unit represented by Formula (C) is 5% by mole or less with respect to all repeating units of the polymer, 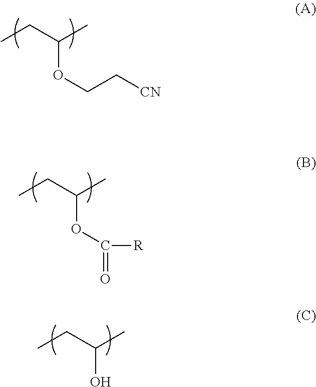
R represents an aliphatic hydrocarbon group which may have a substituent, provided that the aliphatic hydrocarbon group which may have a substituent has 1 to 8 carbon atoms.

2. The polymer according to claim 1,
wherein the aliphatic hydrocarbon group which may have a substituent has 2 to 8 carbon atoms.

3. The polymer according to claim 1,
wherein the content of the repeating unit represented by Formula (A) is 70% by mole or more with respect to all repeating units of the polymer, and
the content of the repeating unit represented by Formula (B) is 1% to 30% by mole with respect to all repeating units of the polymer.

4. A composition comprising:
the polymer according to claim 1; and
a cyano group-containing compound different from the polymer.

5. The composition according to claim 4,
wherein the cyano group-containing compound is a compound represented by Formula (1),
(CN—CH₂CH₂)ₙ-L Formula (1)
L represents an n-valent linking group, and
n represents an integer of 1 to 50.

6. The composition according to claim 4,
wherein the cyano group-containing compound is cyanoethyl sucrose.

7. A piezoelectric composite material comprising:
the polymer according to claim 1; and
piezoelectric particles.

8. The piezoelectric composite material according to claim 7,
wherein the piezoelectric particles include ceramic particles having a perovskite-type or wurtzite-type crystal structure.

9. The piezoelectric composite material according to claim 7,
wherein the piezoelectric particles include any one of lead zirconate titanate, lead lanthanum zirconate titanate, barium titanate, zinc oxide, or a solid solution of barium titanate and bismuth ferrite.

10. The piezoelectric composite material according to claim 7, further comprising:
a cyano group-containing compound different from the polymer.

11. A piezoelectric film comprising:
a piezoelectric layer including the piezoelectric composite material according to claim 7; and
electrode layers provided on both surfaces of the piezoelectric layer.

12. A piezoelectric element comprising:
the piezoelectric film according to claim 11.

13. The polymer according to claim 2,
wherein the content of the repeating unit represented by Formula (A) is 70% by mole or more with respect to all repeating units of the polymer, and
the content of the repeating unit represented by Formula (B) is 1% to 30% by mole with respect to all repeating units of the polymer.

14. A composition comprising:
the polymer according to claim 2; and
a cyano group-containing compound different from the polymer.

15. The composition according to claim 14,
wherein the cyano group-containing compound is a compound represented by Formula (1),
(CN—CH₂CH₂)ₙ-L Formula (1)
L represents an n-valent linking group, and
n represents an integer of 1 to 50.

16. The composition according to claim 5,
wherein the cyano group-containing compound is cyanoethyl sucrose.

17. A piezoelectric composite material comprising:
the polymer according to claim 2; and
piezoelectric particles.

18. The piezoelectric composite material according to claim 17,
wherein the piezoelectric particles include ceramic particles having a perovskite-type or wurtzite-type crystal structure.

19. The piezoelectric composite material according to claim 8,
wherein the piezoelectric particles include any one of lead zirconate titanate, lead lanthanum zirconate titanate, barium titanate, zinc oxide, or a solid solution of barium titanate and bismuth ferrite.

20. The piezoelectric composite material according to claim 8, further comprising:
a cyano group-containing compound different from the polymer.
